(19) United States
(12) Patent Application Publication
(10) Pub. No.: US 2025/0176440 A1
(43) Pub. Date: May 29, 2025

(54) SPIN ORBIT TORQUE MATERIALS, MAGNETIC MEMORY DEVICE INCLUDING THE SAME, AND METHOD FOR FABRICATING SPIN ORBIT TORQUE MATERIALS

(71) Applicants: SAMSUNG ELECTRONICS CO., LTD., Suwon-si (KR); POSTECH RESEARCH AND BUSINESS DEVELOPMENT FOUNDATION, Pohang-si (KR)

(72) Inventors: Won Joon CHO, Suwon-si (KR); Jun Sung KIM, Pohang-si (KR); Sungyu PARK, Pohang-si (KR); Gyu Seung Choi, Pohang-si (KR)

(21) Appl. No.: 18/962,413

(22) Filed: Nov. 27, 2024

(30) Foreign Application Priority Data
Nov. 27, 2023 (KR) 10-2023-0167242

(51) Int. Cl. H10N 50/85; G11C 11/16; G11C 11/18; H10N 50/01; H10N 50/10; H10N 52/80

(52) U.S. Cl. CPC H10N 50/85; G11C 11/161; G11C 11/18; H10N 50/01; H10N 50/10; H10N 52/80

(57) ABSTRACT

A spin orbit torque (SOT) material having a magnetic bilayer structure includes a non-magnetic layer including a Van der Waals topological insulator disposed on a substrate and a magnetic layer including a Van der Waals ferromagnetic body in contact with the non-magnetic layer. A thickness of the non-magnetic layer is determined in a way such that the non-magnetic layer has a topological surface state and the non-magnetic layer exhibits a conductance of a predetermined magnitude.

### CROSS-REFERENCE TO RELATED APPLICATION

This application claims priority to Korean Patent Application No. 10-2023-0167242, filed on Nov. 27, 2023, and all the benefits accruing therefrom under 35 U.S.C. § 119, the content of which in its entirety is herein incorporated by reference.

### BACKGROUND

### 1. Field

The present disclosure relates to a spin orbit torque material, a manufacturing method of the spin orbit torque material, and a magnetic memory device including the spin orbit torque material.

### 2. Description of the Related Art

A magnetoresistive random-access memory (MRAM) is a non-volatile memory that does not lose an information even when a power is turned off. In an electronic device where the MRAM is used as a memory thereof, a computer that retains an information without a power consumption even when a power is turned off and may be used as soon as a power is supplied may be implemented.

Particularly, even when the power is turned off while using a mobile device such as a laptop or a smart device, which is battery-operated, an information may be stored in the MRAM without a battery power consumption, and when being operated several hours later, a work may continue based on the stored information.

### SUMMARY

In an embodiment of the invention, a spin orbit torque (SOT) material having a magnetic bilayer structure includes a non-magnetic layer disposed on a substrate and a magnetic layer in contact with the non-magnetic layer, where a thickness of the non-magnetic layer is determined in a way such that the non-magnetic layer has a topological surface state and the non-magnetic layer exhibits a conductance of a predetermined magnitude.

In another embodiment of the invention, a magnetic memory device includes a spin Hall layer disposed on a substrate, a free layer in contact with the spin Hall layer, a tunneling layer disposed adjacent to a SOT material, and a fixed layer disposed adjacent to the tunneling layer, where a thickness of the spin Hall layer is determined in a way such that the spin Hall layer has a topological surface state and the spin Hall layer exhibits a conductance of a predetermined magnitude.

In another embodiment of the invention, a method for manufacturing an SOT material of a magnetic bilayer structure includes forming a substrate on a magnetic body crystal, forming a magnetic layer having a predetermined thickness by peeling the magnetic body crystal, and forming a non-magnetic layer on the magnetic layer.

### BRIEF DESCRIPTION OF THE DRAWINGS

The above and other features of embodiments of the invention will become more apparent by describing in further detail embodiments thereof with reference to the accompanying drawings, in which:

FIG. 1 illustrates a spin orbit torque (SOT) material according to one or more embodiments;

FIG. 2A to FIG. 2C illustrate a relationship between a thickness of each layer in a SOT material and a magnetization switching therein according to one or more embodiments;

FIG. 2D illustrates a change in a conductance of a SOT material according to one or more embodiments;

FIG. 3 illustrates a manufacturing method of a SOT material according to one or more embodiments;

FIG. 4 illustrates a manufacturing method of SOT material according to one or more embodiments;

FIG. 5 illustrates an electron-spin conversion efficiency of a SOT device according to one or more embodiments;

FIG. 6 illustrates a SOT device according to one or more embodiments;

FIG. 7 illustrates a change in a resistance of a SOT device according to one or more embodiments;

FIG. 8 illustrates a block diagram of an electronic system including a magnetic memory device according to one or more embodiments;

FIG. 9 illustrates a block diagram of an information processing system including a magnetic memory device according to one or more embodiments; and

FIG. 10 illustrates a block diagram of a memory card including a magnetic memory device according to one or more embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the present disclosure, each phrase such as “A or B,” “at least one of A and B,” “at least one selected from A and B,” “at least one of A or B,” “A, B, or C,” “at least one of A, B and C,” “at least one selected from A, B and C,” and “at least one of A, B, or C” may include any one of items listed together in the corresponding one of those phrases, or all possible combinations thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

In a flowchart described with reference to drawings in this specification, the order of operations may be changed, several operations may be merged, some operations may be divided, and specific operations may not be performed.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

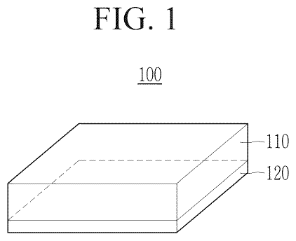

FIG. 1 illustrates a spin orbit torque (SOT) material according to one or more embodiments.

In some embodiments, the SOT material 100 may have a magnetic bilayer structure including a non-magnetic layer 110 and a magnetic layer 120 in contact with the non-magnetic layer 110.

In some embodiments, the non-magnetic layer 110 is a layer where a spin-orbit coupling occurs. When a current flows in a direction parallel to the interlayer interface between the non-magnetic layer 110 and the magnetic layer 120, a spin Hall effect may occur due to a spin-orbit coupling in the non-magnetic layer 110. Due to the spin Hall effect, the trajectory of electron may be separated along spin directions of the electron and the electron having one of two spin directions may be injected into the magnetic layer 110.

In some embodiments, the non-magnetic layer 110 may include (or be defined by) a topological insulator (or topological nonconductor) with high charge-spin conversion efficiency (a SOT efficiency). Because the surface state of the topological insulator has a strong spin-momentum coupling, the non-magnetic layer 110 may exhibit high SOT efficiency.

In an embodiment, the non-magnetic layer 110 may include or be defined by a Van der Waals topological insulator in which layers of the materials are bonded to each other by Van der Waals force, which has a weak bonding force between the layers. In such an embodiment, due to the weak interlayer bonding force in the non-magnetic layer 110, the non-magnetic layer 110 may exhibit a uniform surface state. That is, the interface between the non-magnetic layer 110 and the magnetic layer 120 may be uniform, and thus information loss of a spin current supplied from the non-magnetic layer 110 to the magnetic layer 120 may be minimized.

In an embodiment, for example, the non-magnetic layer 110 may include a Sn-doped BSTS (BiSbTeS). Because the Sn-doped BSTS has very low bulk electrical conductance, a transferring contribution from switching current supplied to the non-magnetic layer 110 to the spin current to the interface between the layers is relatively high. In an embodiment, at least one selected from sulfur (S), vanadium (V), or calcium (Ca) may be doped in the non-magnetic layer 110. In some embodiments, the maximum amounts of elements to be doped in the non-magnetic layer 110 may be 10% of bismuth (Bi) in BiₓSb₂₋ₓTe₂S (0.1×bismuth(x)).

In some embodiments, a thickness of the non-magnetic layer 110 may be determined to be a value that may maximize the effect by the topological state of the Van der Waals topological insulator. In such embodiment, a thickness of the topological insulator that may maximize the effect (e.g., the conductance) of the topological state of the topological insulator may be determined. For example, when the conductance of the non-magnetic layer 110 is maximum, the spin Hall effect may be maximized in the non-magnetic layer 110, accordingly, the spin current derived from the switching current supplied to the non-magnetic layer 110 may be supplied to the magnetic layer 120 as much as possible.

In some embodiments, the magnetic layer 120 is a layer in which a spin transfer torque is generated by the spin current supplied from the non-magnetic layer 110 and may include a ferromagnetic body. When the spin transfer torque is generated in the magnetic layer 120, the magnetization direction of the magnetic layer 120 may be changed (a magnetization switching may occur by the spin current).

In some embodiments, the magnetic layer 120 may include a Van der Waals ferromagnetic body. In such embodiments, due to the weak interlayer bonding force of the magnetic layer 120, the magnetic layer 120 may be easily fabricated in a planar form (as a two-dimensional material) with a thin thickness (a thickness of a level of a single or several atom layers) and may exhibit a uniform surface state. In an embodiment, for example, the magnetic layer 120 may include Fe₃GeTe₂ or Fe₃GaTe₂ (hereinafter, will be referred to as ‘FGT’).

In some embodiments, the FGT is a Van der Waals ferromagnetic body with metallic properties and is easily supplied with a spin current from the non-magnetic layer 110. In such embodiments, although the FGT has a relatively strong perpendicular magnetic anisotropy (PMA) the magnetization switching in the magnetic layer 120 may easily occur even with a small magnitude of the switching current.

In some embodiments, the SOT material 100 may include a Van der Waals topological insulator (Sn-doped BSTS) as the non-magnetic layer 110 and a Van der Waals ferromagnetic body (Fe₃GeTe₂ or Fe₃GaTe₂) as the magnetic layer 120. The material composition of the Van der Waals topological insulator may be determined in a way such that the conductance of the bulk state is minimized. Because the Van der Waals ferromagnetic body has a relatively high conductance compared to the Van der Waals topological insulator, the thickness of the magnetic layer 120 may be thinner than the thickness of the non-magnetic layer 110.

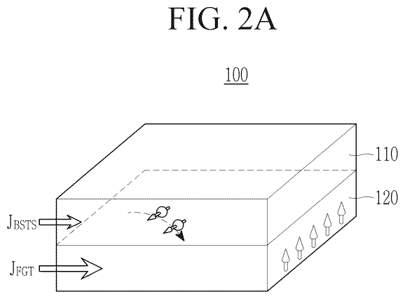

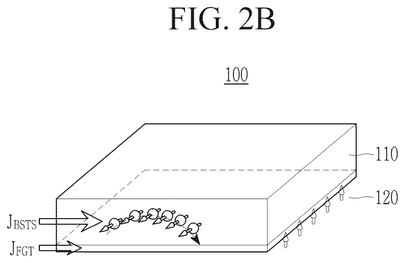

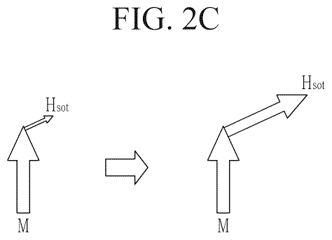

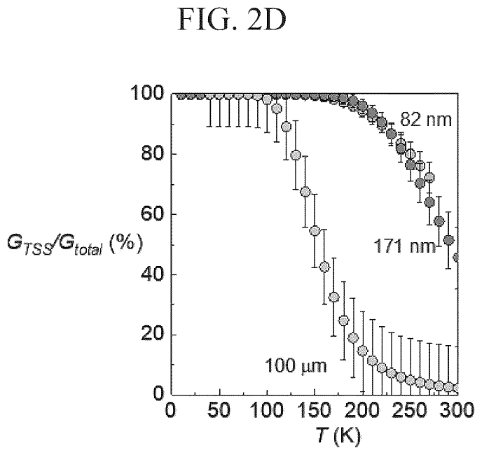

FIG. 2A to FIG. 2C illustrate a relationship between a thickness of each layer in a SOT material and a magnetization switching therein according to one or more embodiments. FIG. 2D illustrates a graph showing a change in a conductance of a SOT material according to one or more embodiments.

Referring to FIG. 2A and FIG. 2B, as shown in Equation 1 below, the current density \vec{J} of the switching current supplied to the non-magnetic layer 110 may include a component \vec{J}_{BSTS} that is converted into a spin current in the non-magnetic layer 110 by the spin Hall effect and a component \vec{J}_{FGT} corresponding to a leakage current that leaks to the magnetic layer 120.

$$\vec{J} = {\vec{J}}_{BSTS} + {\vec{J}}_{FGT} \qquad ( Equation 1 )$$

Referring to Equation 1 above, some of the switching current supplied to the non-magnetic layer 110 for the SOT magnetization switching may be leaked to the magnetic layer 120, and then the magnitude of the leakage current may be determined by the conductance and/or the resistance of the magnetic layer 120 and the non-magnetic layer 110.

Referring to FIG. 2A, the current density \vec{J}_{FGT} of the leakage current to the magnetic layer 120 may be greater than the current density \vec{J}_{BSTS} of the non-magnetic layer 110 and greater than the current density of \vec{J}_{FGT} in FIG. 2B. Therefore, in this case, referring to FIG. 2C, the magnetic field Hₛₒₜ caused by the spin current supplied to the magnetic layer 120 is relatively weak and the magnetic field M of the magnetic layer 120 may be switched relatively little in FIG. 2A. However, referring to FIG. 2B, the current density \vec{J}_{FGT} of the leakage current to magnetic layer 120 may be less than the current density \vec{J}_{BSTS} of the non-magnetic layer 110 and less than the current density of \vec{J}_{FGT} in FIG. 2A. Therefore, in this case, referring to FIG. 2C, the magnetic field Hₛₒₜ caused by the spin current supplied to the magnetic layer 120 may be relatively strong and the magnetic field M of the magnetic layer 120 may be switched relatively high in FIG. 2B.

Referring to FIG. 2C, as the leakage current to the magnetic layer 120 decreases, the magnetization switching of the magnetic layer 120 may occur significantly even with a same magnitude of the switching current. In other words, when the thickness of the magnetic layer 120 decreases and then the resistance of the magnetic layer 120 increases, the leakage current to the magnetic layer 120 may be reduced, and accordingly, relatively more spin current due to the spin Hall effect in the non-magnetic layer 110 may be supplied to the magnetic layer 120.

In general, since Fe₃GeTe₂ and Fe₃GaTe₂ have relatively high conductance compared to Sn-doped BSTS, when the thickness of the non-magnetic layer 110 and the magnetic layer 120 are similar to each other, a large portion of the switching current may be leaked to the magnetic layer 120, and thus the current and the electric power used for the magnetization switching of the SOT material may increase. Therefore, the thickness of the magnetic layer 120 may be desired to be minimized to minimize the leakage current into the magnetic layer 120.

In a thin membrane such as the magnetic layer 120, as the thickness of the magnetic layer 120 becomes thinner, the resistance of the magnetic layer 120 increases, therefore, when the thickness of the magnetic layer 120 is minimized, the resistance of the magnetic layer 120 may be maximized. When the resistance of the magnetic layer 120 is maximized, the leakage current to the magnetic layer 120 may be reduced.

When the thickness of the magnetic layer 120 becomes thin, the ferromagnetic characteristic (e.g., the perpendicular magnetic anisotropy) of the magnetic layer 120 may not be sustained. Therefore, the thickness of the magnetic layer 120 may be determined to be as thin as possible within a range in which the ferromagnetic characteristic is sustained.

In some embodiments, the Van der Waals ferromagnetic body like the FGT, which may be used as the magnetic layer 120, may maintain ferromagnetic characteristics even in a single molecule layer. In other words, the FGT (Fe₃GeTe₂ or Fe₃GaTe₂) with the single molecule layer may maintain the magnetization state in the vertical direction when there is no magnetic field caused by the spin current supplied from the non-magnetic layer 110. Therefore, the magnetic layer 120 may be manufactured as the Van der Waals ferromagnetic body with the single molecule layer.

In some embodiments, where the magnetic layer 120 is manufactured from a ferromagnetic metal (e.g., CoPt, CoFeB, CoTb, etc.) rather than the Van der Waals ferromagnetic body, the thickness of the magnetic layer 120 may be determined to be a minimum value in the range in which the ferromagnetic characteristic of the ferromagnetic metal is maintained. For example, when the ferromagnetic characteristic of a specific ferromagnetic metal is maintained only up to n molecule layers and the ferromagnetic characteristic of the ferromagnetic metal disappears or weakens in (n−1) molecule layers, the thickness of the magnetic layer 120 may be determined as the n molecule layers.

In some embodiments, the thickness of the magnetic layer 120 may be determined from the single molecule layer to threshold molecule layers determined based on the change in the resistance of the stacked structure of the non-magnetic layer 110/the magnetic layer 120. That is, the change in the resistance according to the current change represents the SOT characteristic when the thickness of the magnetic layer 120 is equal to or less than the threshold molecule layers. For example, when the Van der Waals ferromagnetic body of the magnetic layer 120 is Fe₃GeTe₂, the change in the resistance according to the current change represents the SOT characteristic when the thickness of the magnetic layer 120 is equal to or less than six molecule layers, and therefore, the thickness of the magnetic layer 120 may be in a ranged from one to six molecule layers. From experimental results that when Fe₃GeTe₂ is stacked with the seven molecule layers, the change in the resistance of the stacked structure of the non-magnetic layer 110/magnetic layer 120 does not show the SOT characteristic, it may be determined that Fe₃GeTe₂ may be stacked up to the six molecule layers.

In some embodiments, where the Van der Waals ferromagnetic body of the magnetic layer 120 is Fe₃GaTe₂, the change in the resistance according to the current change shows the SOT characteristic when the thickness of the magnetic layer 120 is equal to or less than eighteen molecule layers, and therefore, the thickness of the magnetic layer 120 may be in a range from one to eighteen molecule layers. From experimental results that when Fe₃GaTe₂ is stacked with the nineteen molecule layers, the resistance change of the stacked structure of the non-magnetic layer 110/magnetic layer 120 does not show the SOT characteristic, it may be determined that Fe₃GaTe₂ may be stacked up to the eighteen molecule layers.

In some embodiments, the thickness of the magnetic layer 120 may be determined based on a previously determined ratio for the thickness of the non-magnetic layer 110, which was previously determined based on the topological state. When the thickness range of the non-magnetic layer 110 is determined based on the topological state of the Van der Waals topological insulator, the thickness of the magnetic layer 120 may be determined based on a predetermined ratio according to the design constraints of the SOT material. For example, when a predetermined resistance ratio of the non-magnetic layer 110 and the magnetic layer 120 is a:b according to the design constraints of the SOT material, a thickness threshold value T_{threshold} of the magnetic layer 120 may be determined from a thickness range c [nanometer (nm)] to d [nm] of the non-magnetic layer 110 determined based on the topological state of the Van der Waals topological insulator.

In some embodiments, to maximize the spin Hall effect occurring in the non-magnetic layer 110, a ratio between the current (or the current density of the current) flowing in the non-magnetic layer 110 and the current (or the current density of the current) flowing in the magnetic layer may be determined in advance. For example, to maximize the spin Hall effect, the current density \vec{J}_{BSTS} of the current flowing in the non-magnetic layer 110 may be n times greater than three times (n≥3) than the current density \vec{J}_{FGT} of the current flowing in the magnetic layer 120 and the thickness of the magnetic layer 120 may be determined based on the predetermined current ratio between the non-magnetic layer 110 and the magnetic layer 120.

In some embodiments, as the thickness of the non-magnetic layer 110 increases, the current flowing in the topological surface state of the non-magnetic layer 110 may decrease and the current flowing in the bulk state of the non-magnetic layer 110 may increase. Referring to FIG. 2D, it may be seen that as the temperature of the non-magnetic layer 110 decreases, the conductance G (TSS: topological surface state) of the non-magnetic layer 110 tends to increase. Here, it can be seen that when the thickness of the non-magnetic layer 110 is 100 micrometers (μm), the conductance of the bulk state of the non-magnetic layer 110 is high at a room temperature (e.g., about 288K), so current through surface states of the non-magnetic layer is low. However, when the thickness of the non-magnetic layer 110 is 82 nm and 171 nm, the conductance of the bulk state of the non-magnetic layer 110 is low, so current through surface states of the non-magnetic layer is high.

As shown in FIG. 2D, when the thickness of the non-magnetic layer 110 becomes smaller than the predetermined value (about 10 nm), the topological surface state of the non-magnetic layer 110 changes, such that the SOT efficiency may be deteriorated. Therefore, the thickness of the non-magnetic layer 110 may be determined by whether the topological surface state of the non-magnetic layer 110 is maintained and whether the non-magnetic layer 110 exhibits a conductance of a predetermined magnitude. That is, the thickness of the non-magnetic layer 110 may be determined in a way such that the topological surface state of the non-magnetic layer 110 is maintained and the non-magnetic layer 110 exhibits a conductance of a predetermined magnitude. That is, the non-magnetic layer 110 may have a predetermined thickness that allows the topological surface state of the non-magnetic layer 110 to be maintained and the non-magnetic layer 110 to exhibit a conductance of a predetermined magnitude. In an embodiment, for example, the thickness range of the non-magnetic layer 110, which the non-magnetic layer 110 may maintain the topological surface state and simultaneously produce the conductance of a predetermined magnitude, may be a range of about 10 nm to about 200 nm.

In an embodiment, as described above, the SOT efficiency of the non-magnetic layer may be maximized by using the Van der Waals topological insulator and the leakage current into the magnetic layer may be minimized by using the Van der Waals ferromagnetic body.

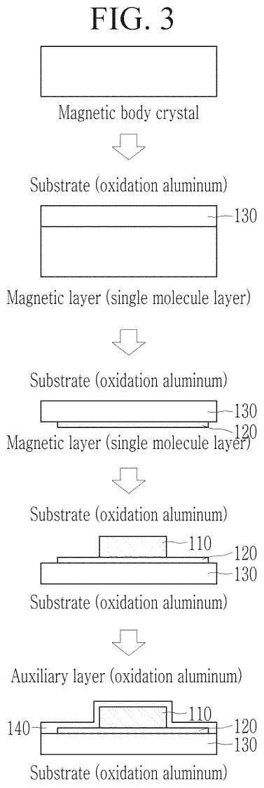

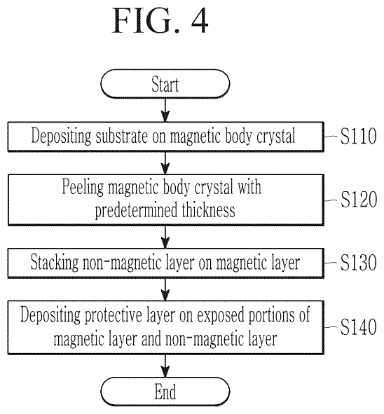

FIG. 3 illustrates a manufacturing method of a SOT material according to one or more embodiments. FIG. 4 illustrates a flowchart showing the manufacturing method of SOT material according to one or more embodiments.

In some embodiments, the magnetic layer 120 may be formed or manufactured through an oxide deposition peeling method that peels off a magnetic body crystal on which a substrate 130 is deposited. The non-magnetic layer 110 may then be deposited on the magnetic layer 120. The exposed surfaces of the non-magnetic layer 110 and the magnetic layer 120 may be protected by an additionally deposited protective layer 140 to prevent a surface oxidation from occurring.

Referring to FIGS. 3 and 4, in an embodiment, the substrate 130 may be deposited (or formed) on one side of the magnetic body crystal (S110). The magnetic body crystal may include a ferromagnetic metal such as CoPt, CoFeB, or CoTb, for example, or a Van der Waals ferromagnetic body such as FeₓGeTe₂ or FeₓGaTe₂, for example. The substrate 130 may include a metal oxide such as aluminum oxide.

In such an embodiment, the magnetic body crystal may be delaminated with a predetermined thickness to form a magnetic layer 120 (S120). The thickness of the magnetic layer 120 may be equal to the thickness of several molecule layers. In some embodiments, where the magnetic body crystal is a Van der Waals ferromagnetic body, the magnetic layer 120 may be manufactured with one molecule layer, that is, the single molecule layer.

In such an embodiment, the non-magnetic layer 110 may be formed on the magnetic layer 120 (S130). As a result, the magnetic layer 120 and the non-magnetic layer 110 may be sequentially positioned on the substrate 130. The non-magnetic layer 110 may include heavy metal (tungsten (W), tantalum (Ta), platinum (Pt), etc.) or topological metalloid (WTe₂, etc.) or topological insulator (Bi₂Se₃, Bi₂Te₃, etc.). In some embodiments, Sn-doped BiₓSb₂₋ₓTe₂S (Sn-doped BSTS), which is the Van der Waals topological insulator, may be used to form the non-magnetic layer 110.

In such an embodiment, the manufacturing of the SOT material 100 may be completed by depositing a protective layer 140 to protect the exposed portions of the non-magnetic layer 110 and the magnetic layer 120 from moisture, oxygen, etc. (S140). The protective layer 140 may include a metal oxide such as aluminum oxide. In such an embodiment, an electrode pattern may be formed on the SOT material 100, and processes such as an etching may be performed accordingly to manufacture an SOT device.

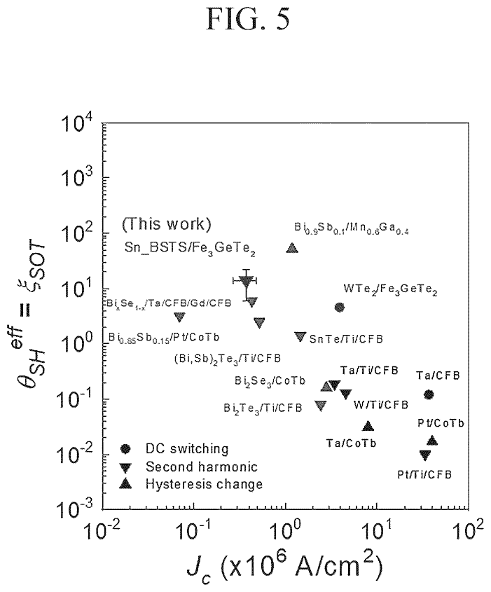

FIG. 5 illustrates an electron-spin conversion efficiency of a SOT device according to one or more embodiments.

In FIG. 5, θ_{SH} is a spin Hall angle and θ_{SH}^{eff} may represent an electron-spin conversion efficiency regarding a ratio at which a spin current is generated from a charge current flowing in a plane direction.

Referring to FIG. 5, the combination of Sn-doped BSTS and Fe₃GeTe₂ or Fe₃GaTe₂, which are the SOT material 100 according to one or more embodiments, shows relatively high electron-spin conversion efficiency even when a relatively small switching current (J_{C}) is supplied. In other words, the SOT material 100 according to one or more embodiments may obtain high electron-spin conversion efficiency with a smaller switching current compared to conventional materials shown in FIG. 5.

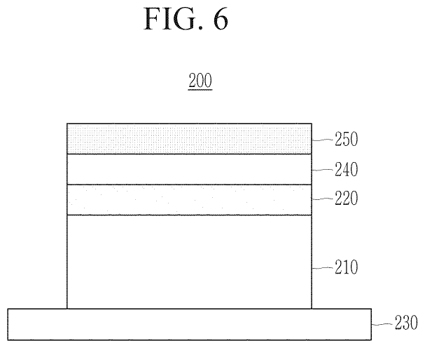

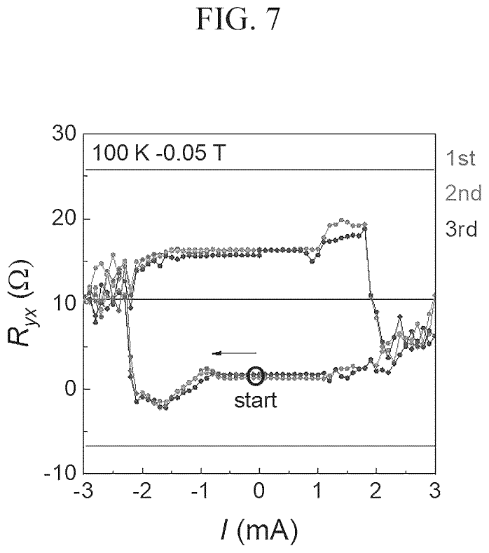

FIG. 6 illustrates a SOT device according to one or more embodiments. FIG. 7 illustrates a change in a resistance of a SOT device according to one or more embodiments.

Referring to FIG. 6, a SOT device 200 according to one or more embodiments may include a spin Hall layer 210, a free layer 220, a substrate 230, a tunneling layer 240, and a fixed layer 250.

In such embodiments, the spin Hall layer 210 and the free layer 220 may include or be defined by the SOT material. The spin Hall layer 210 may correspond to the non-magnetic layer 110 of the SOT material 100 and the free layer 220 may correspond to the magnetic layer 120 of the SOT material 100. In some embodiments, the spin Hall layer 210 may include or be defined by the Van der Waals topological insulator. In such embodiments, the free layer 220 may include or be defined by the Van der Waals ferromagnetic body.

In some embodiments, the spin Hall effect may occur within the spin Hall layer 210 by the switching current supplied to the spin Hall layer 210 and the spin current generated by the spin Hall effect may be supplied to the free layer 220. The spin current supplied to the free layer 220 may change the magnetization direction of the free layer 220, and then the SOT device 200 may be operated as a magnetic memory device by using the change in a tunneling magnetic resistance (TMR) between the free layer and the fixed layer that occurs due to the change in magnetization of the free layer 220.

In some embodiments, the resistance of the SOT material 100 may be changed depending on the magnitude and the direction of the switching current and the SOT device 200 may operate as a memory device using the change of the resistance of the SOT material. Referring to FIG. 7, when the switching current supplied to the SOT material 100 increases in a negative direction, the resistance of the SOT material 100 may increase from a value close to 0 ohm (Ω) to near 15Ω. When the switching current increases again in a positive direction, the resistance of the SOT material 100 may decrease from around 15 Ω to a value close to 0Ω. In other words, depending on the magnitude and the direction of the switching current, the resistance of the SOT material 100 changes dramatically into two values with predetermined differences, and the SOT device 200 may operate as a magnetic memory device using this characteristic of the SOT material 100.

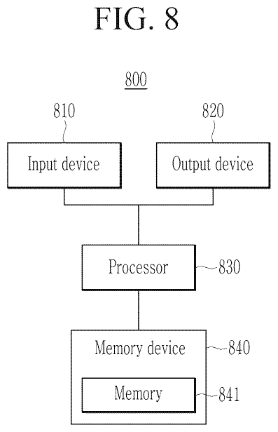

FIG. 8 illustrates an electronic system including a magnetic memory device according to one or more embodiments.

Referring to FIG. 8, an embodiment of an electronic system 800 may include an input device 810, an output device 820, a processor 830, and a memory device 840. In some embodiments, the memory device 840 may include a cell array including a non-volatile memory cell and a peripheral circuit for operations such as read/write for the memory cell.

In some other embodiments, the memory device 840 may include a non-volatile memory device and a memory controller.

The memory 841 included in the memory device 840, according to one or more embodiments described above with reference to FIG. 1 to FIG. 7, may include the SOT material or the magnetic memory device including the SOT material.

The processor 830 may be connected to the input device 810, the output device 820, and the memory device 840 through an interface, and may control the overall operations.

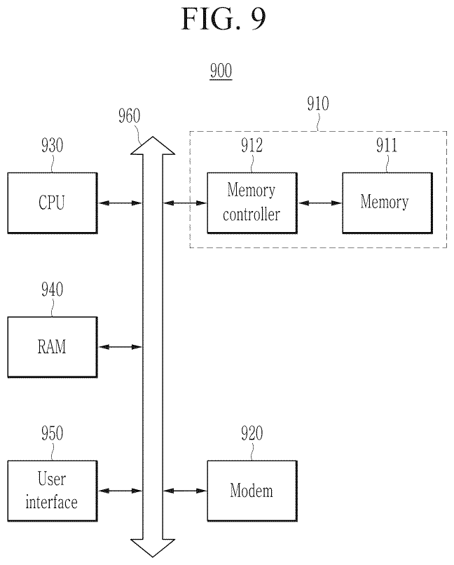

FIG. 9 illustrates an information processing system including a magnetic memory device according to one or more embodiments.

Referring to FIG. 9, an embodiment of an information processing system 900 may include a non-volatile memory system 910, a modem 920, a central processing unit (CPU) 930, a random access memory (RAM) 940, and a user interface 950 that are electrically connected through a bus 902.

The non-volatile memory system 910 may include a memory 911 and a memory controller 912. A data processed by the CPU 930 or a data input from outside may be stored in the non-volatile memory system 910.

The non-volatile memory system 910 may include a non-volatile memory such as MRAM, phase-change RAM (PRAM), resistive RAM (RRAM), and ferroelectric RAM (FRAM). In an embodiment, at least one selected from the memory 911 and the RAM 940 may include the SOT material according to embodiments described above with reference to FIG. 1 to FIG. 7 or a magnetic memory device including the SOT material.

The information processing system 900 may be used in a portable computer, a web tablet, a wireless phone, a mobile phone, a digital music player, a memory card, a MP3 player, a navigation, a portable multimedia player (PMP), a solid state disk (SSD) or a household appliances.

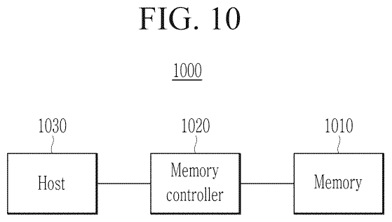

FIG. 10 illustrates a memory card including a magnetic memory device according to one or more embodiments.

An embodiment of the memory card 1000 may include a memory 1010 and a memory controller 1020.

The memory 1010 may store a data. In some embodiments, the memory 1010 has a non-volatile characteristic capable of maintaining a stored data as it is even if a power supply is interrupted. The memory 1010 may include the SOT material according to embodiments described above with reference to FIG. 1 to FIG. 7 or a magnetic memory device including the SOT material.

The memory controller 1020 may read a data stored in the memory 1010 or store a data in memory 1010 in response to a read/write request from the host 1030.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A spin orbit torque material having a magnetic bilayer structure, the spin orbit torque material comprising:
a non-magnetic layer disposed on a substrate; and
a magnetic layer in contact with the non-magnetic layer,
wherein a thickness of the non-magnetic layer is determined in a way such that the non-magnetic layer has a topological surface state and the non-magnetic layer exhibits a conductance of a predetermined magnitude.

2. The spin orbit torque material of claim 1, wherein
the non-magnetic layer includes a Van der Waals topological insulator.

3. The spin orbit torque material of claim 2, wherein
the Van der Waals topological insulator includes BiₓSb₂₋ₓTe₂S doped with at least one selected from tin (Sn), sulfur (S), vanadium (V), or calcium (Ca).

4. The spin orbit torque material of claim 3, wherein
a maximum amount of elements doped in the BiₓSb₂₋ₓTe₂S is 10% of bismuth (Bi).

5. The spin orbit torque material of claim 1, wherein
the magnetic layer includes a Van der Waals ferromagnetic body.

6. The spin orbit torque material of claim 5, wherein
the Van der Waals ferromagnetic body includes Fe₃GeTe₂ or Fe₃GaTe₂.

7. The spin orbit torque material of claim 6, wherein
a thickness of the magnetic layer is in a range from a single molecule layer to threshold molecule layers where changes in resistance of the spin orbit torque material exhibit spin orbit torque characteristics.

8. The spin orbit torque material of claim 7, wherein
when the Van der Waals ferromagnetic body includes the Fe₃GeTe₂, the thickness of the magnetic layer is in a range from the single molecule layer to seven molecule layers, and
when the Van der Waals ferromagnetic body includes the Fe₃GaTe₂, the thickness of the magnetic layer is in a range from the single molecule layer to eighteen molecule layers.

9. A magnetic memory device comprising:
a spin Hall layer disposed on a substrate;
a free layer in contact with the spin Hall layer;
a tunneling layer disposed adjacent to the free layer; and
a fixed layer disposed adjacent to the tunneling layer,
wherein a thickness of the spin Hall layer is determined in a way such that the spin Hall layer has a topological surface state and the spin Hall layer exhibits a conductance of a predetermined magnitude.

10. The magnetic memory device of claim 9, wherein
the spin Hall layer includes a Van der Waals topological insulator.

11. The magnetic memory device of claim 10, wherein
the Van der Waals topological insulator includes BiₓSb₂₋ₓTe₂S doped with at least one selected from tin (Sn), sulfur (S), vanadium (V), or calcium (Ca).

12. The magnetic memory device of claim 11, wherein
a maximum amount of elements doped in the BiₓSb₂₋ₓTe₂S is 10% of bismuth (Bi).

13. The magnetic memory device of claim 9, wherein
the free layer includes a Van der Waals ferromagnetic body.

14. The magnetic memory device of claim 13, wherein
the Van der Waals ferromagnetic body includes Fe₃GeTe₂ or Fe₃GaTe₂.

15. The magnetic memory device of claim 14, wherein
a thickness of the free layer is in a range from a single molecule layer to threshold molecule layers where changes in resistance of the spin Hall layer and the free layer represent spin orbit torque characteristics.

16. The magnetic memory device of claim 15, wherein
when the Van der Waals ferromagnetic body includes Fe₃GeTe₂, the thickness of the free layer is in a range from the single molecule layer to seven molecule layers, and
when the Van der Waals ferromagnetic body includes Fe₃GaTe₂, the thickness of the free layer is in a range from the single molecule layer to eighteen molecule layers.

17. A method for manufacturing a spin orbit torque material having a magnetic bilayer structure, the method comprising:
forming a substrate on a magnetic body crystal;
forming a magnetic layer having a predetermined thickness by peeling the magnetic body crystal; and
forming a non-magnetic layer on the magnetic layer.

18. The method of claim 17, wherein
the forming the substrate on the magnetic body crystal includes depositing aluminum oxide layer as the substrate on the magnetic body crystal.

19. The method of claim 18, further comprising:
depositing a protective layer on exposed portions of the magnetic layer and the non-magnetic layer.

20. The method of claim 17, wherein
the magnetic layer includes a Van der Waals ferromagnetic body, and
the non-magnetic layer includes a Van der Waals topological insulator.
